(19) United States
(12) Patent Application Publication
(10) Pub. No.: US 2019/0371771 A1
(43) Pub. Date: Dec. 5, 2019

(54) LIGHT EMITTING DIODE ARRAY STRUCTURE AND DISPLAY DEVICE

(71) Applicant: Yungu (Gu'an) Technology Co., Ltd., Langfang (CN)

(72) Inventors: Rubo XING, Langfang (CN); Xiaolong YANG, Langfang (CN); Qi SHAN, Langfang (CN); Jiantai WANG, Langfang (CN)

(21) Appl. No.: 16/540,469

(22) Filed: Aug. 14, 2019

Related U.S. Application Data
(63) Continuation of application No. PCT/CN2018/087334, filed on May 17, 2018.

(30) Foreign Application Priority Data
Sep. 28, 2017 (CN) 201721272702.0

(51) Int. Cl. H01L 25/075; H01L 23/538; H01L 33/12; H01L 33/32; H01L 33/50; H01L 33/56; H01L 23/14

(52) U.S. Cl. CPC H01L 25/0753; H01L 23/5387; H01L 33/12; H01L 23/145; H01L 33/505; H01L 33/56; H01L 33/32

(57) ABSTRACT

An LED array structure and a display device are provided. The LED array structure includes a first substrate, LEDs formed on the first substrate, and an elastic portion formed from an elastic material filled between the LEDs and the first substrate, and/or between the adjacent LEDs. In the LED array structure and the display device according to the embodiments of the present application, the elastic portion is filled between the LEDs and the first substrate. Therefore, the elastic portion is used as a stress release layer during bending process of a flexible screen, so as to prevent damage to a brittle LED chip and improve bending resistance of the LED array structure.

### CROSS-REFERENCE TO RELATED APPLICATIONS

This application is a continuation of International Application No. PCT/CN2018/087334 filed on May 17, 2018, which claims priority to Chinese patent application No. 201721272702.0 filed on Sep. 28, 2017. Both applications are incorporated herein by reference in their entireties.

### TECHNICAL FIELD

Embodiments of the present application relate to the field of display technologies, and particularly to a Light Emitting Diode (LED) array structure and a display device.

### BACKGROUND

The Micro-LED technology refers to a technology of integrating high-density LED arrays in a micro size. Pixel distances may be reduced from millimeter-level to micrometer-level when the Micro-LED technology is applied to the display field. Compared with other micro-display technologies, this kind of display device using the micro-LED technology has a self-luminescence function, and an optical system thereof is simple. Therefore, the volume, weight and cost of the whole system can be reduced, and characteristics of low power consumption and fast response can be achieved.

In an implementing process, there will be the following problem: bending reliability of a brittle LED device is hard to be ensured when a flexible panel is manufactured.

### SUMMARY

Main objects of the present application are to provide an LED array structure and a display device, so as to solve problems of the prior art.

In order to achieve the above objects, in a first aspect, an LED array structure according to embodiments of the present application includes a first substrate, a plurality of LEDs formed on the first substrate, and an elastic portion formed from elastic material filled between the plurality of LEDs and the first substrate, and/or between the adjacent LEDs.

Optionally, the elastic portion is made of at least one of polyurethane, silicone rubber and polyimide.

Optionally, each of the plurality of LEDs includes an electron layer, a light emitting layer, a hole layer and an electrode, and the light emitting layer is formed between the electron layer and the hole layer.

Optionally, the electron layer, the light emitting layer and the hole layer are coated by the elastic portion.

Optionally, the electron layer is a n-type GaN layer, and the hole layer is a p-type GaN layer.

Optionally, the electron layer is the p-type GaN layer, and the hole layer is the n-type GaN layer.

Optionally, the LED array structure further includes a buffer layer formed on the hole layer or the electron layer.

Optionally, the buffer layer is disposed away from the light emitting layer.

Optionally, a material of the buffer layer includes either or both of aluminum nitride and gallium nitride.

Optionally, a material of the first substrate includes at least one of polyethylene glycol terephthalate, polymethyl methacrylate, polyimide, polyurethane and silicone rubber.

Optionally, the LED array structure further includes a second substrate for bonding with the first substrate, and the second substrate includes light conversion layers.

Optionally, the second substrate is attached to a side of the first substrate on which the plurality of LEDs are disposed.

In addition, in order to achieve the above objects, in a second aspect, a display device according to the embodiments of the present application includes the LED array structure mentioned in any one of the above embodiments.

In the LED array structure and the display device according to the embodiments of the present application, the elastic portion is filled between the plurality of LEDs and the first substrate. Therefore, the elastic portion is used as a stress release layer during bending process of a flexible screen, so as to prevent damage to a brittle LED chip and improve bending resistance of the LED array structure.

### BRIEF DESCRIPTION OF DRAWINGS

FIG. 1 is a schematic structural diagram of an LED array structure according to an embodiment of the present application.

Implementation of objects, functional features and advantages of the present application will be further described with reference to embodiments and an accompanying drawing.

### DETAILED DESCRIPTION

In descriptions of embodiments of the present application, it may be understood that orientations or positional relationships indicated in terms such as “center”, “upper”, “lower”, “front”, “back”, “left”, “right”, etc. refer to orientations or positional relationships shown in an accompanying drawing. The terms are merely for facilitating and simplifying the descriptions of the present application, rather than indicating or implying that a device or a component referred to has a specific orientation, and is constructed and operated in the specific orientation. Therefore, the terms cannot be understood to be limitations of the present application. Moreover, terms such as “first” and “second” are used for the descriptions only and are not to be construed as indicating or implying a relative importance.

In the descriptions of the embodiments of the present application, it may be noted that terms such as “installation”, “connected” and “connection” may be understood broadly unless clearly defined and limited. For example, the “connection” may refer to one of a fixed connection, a detachable connection and an integral connection; or refer to a mechanical connection or an electrical connection; or refer to one of a direct connection, an indirect connection through an intermediate medium, and an internal connection between two components. For those skilled in the art, specific meanings of the above terms in the present application may be understood according to specific circumstances. In addition, in the descriptions of the present application, unless otherwise stated, meanings of “multiple” and “several” are two or more.

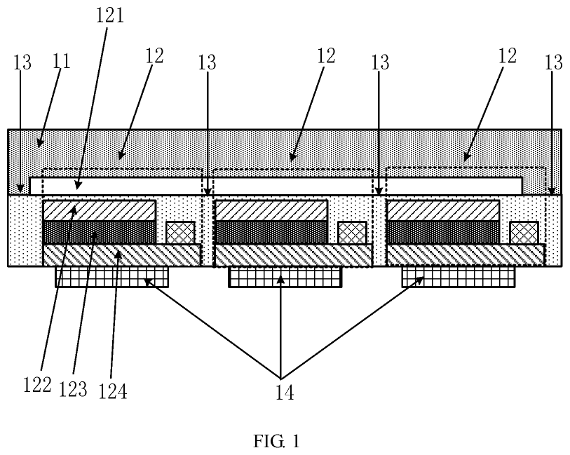

As shown in FIG. 1, an LED array structure according to a first embodiment of the present application includes a first substrate 11, a plurality of LEDs 12 formed on the first substrate 11, and an elastic portion 13 formed from the elastic material filled between the LEDs 12 and between the LEDs 12 and the first substrate 11.

In the embodiment, a material of the first substrate 11 may be selected from flexible organic materials such as polyethylene glycol terephthalate, polymethyl methacrylate, polyimide, polyurethane, silicone rubber and so on. The number of kinds of materials included in the first substrate 11 is not limited.

Each of the LEDs 12 includes an electron layer 122, a light emitting layer 123, a hole layer 124 and an electrode 121. The light emitting layer 123 is formed between the electron layer 122 and the hole layer 124.

It may be understood that when the electron layer 122 is disposed adjacent to the first substrate 11, and then the hole layer 124 is located away from the first substrate 11. When the hole layer 124 is disposed adjacent to the first substrate 11, and then the electron layer 122 is located away from the first substrate 11. That is, positions of the electron layer 122 and the hole layer 124 of the LED array structure shown in FIG. 1 may be interchanged.

In an embodiment of the present application, the elastic portion 13 is only filled between the LEDs 12 and the first substrate 11. The adjacent LEDs 12 doesn't have any elastic portion 13 filled there between. It may be understood that compared with that the elastic portion 13 is filled between the LEDs 12 and the first substrate 11 and between the adjacent LEDs 12, a process flow is simplified and production cost is reduced while bending reliability is ensured according to the LED array structure of the embodiment.

Similarly, in another embodiment of the present application, the elastic portion 13 is only filled between the adjacent LEDs 12. That is, the elastic portion 13 is no longer filled between the LEDs 12 and the first substrate 11. In a same manner, the process flow is simplified and the production cost is reduced while the bending reliability is ensured according to the LED array structure of the embodiment.

Preferably, the LED array structure further includes buffer layers formed on the hole layers 124 or the electron layers 122 of the LEDs 12. For example, the buffer layers are formed on sides of the hole layers 124 or the electron layers 122 away from the light emitting layers 123.

In an embodiment, as shown in FIG. 1, the LED array structure further includes the buffer layers (not shown in the accompanying drawing) formed on the hole layers 124. For example, the buffer layers are formed on the sides of the hole layers 124 away from the light emitting layers 123.

In an embodiment, the LED array structure (not shown) further includes the buffer layers (not shown in the accompanying drawing) formed on the electron layers 122. For example, the buffer layers are formed on the sides of the electron layers 122 away from the light emitting layers 123.

It may be understood that materials of the buffer layers in the above embodiments may be selected from materials such as aluminum nitride (AlN), gallium nitride (GaN) and so on. AlN and GaN have many advantages such as small thermal expansion coefficient, strong corrosion resistance, high heat resistance and strong stability. Therefore, buffering capacity of the buffer layers may be greatly improved by using AlN and GaN as the materials of the buffer layers.

In an embodiment of the present application, the elastic portion 13 includes at least one of polyurethane, silicone rubber and polyimide. It may be understood that an LED chip is coated by filling the elastic portion 13 between the LEDs 12 and between the LEDs 12 and the first substrate 11. Therefore, the elastic portion 13 is used as a stress release layer during a bending process of a flexible screen, so as to prevent damage to the brittle LED chip. In addition, the materials such as polyurethane, silicone rubber and polyimide have many excellent properties such as high flexibility and resilience, excellent oil resistance, solvent resistance, oxidative stability and so on. Therefore, elasticity and stability of the elastic portion 13 may be greatly improved by using the materials such as polyurethane, silicone rubber and polyimide as the elastic portion 13. Thereby, the bending stability of the LED array structure is further improved.

It may be noted that when the LED chip is coated by the elastic portion 13, the electron layers 122, the light emitting layers 123 and the hole layers 124 are all coated, but the electrodes 121 are not coated.

In the embodiment, the electron layers 122 are n-type GaN layers, the hole layers 124 are p-type GaN layers; or the electron layers 122 are the p-type GaN layers, and the hole layers 124 are the n-type GaN layers. Referring to FIG. 1 again, in the embodiment, the LED array structure further includes a second substrate attached to the first substrate 11. The second substrate includes a plurality of light conversion layers 14. The second substrate is attached to the first substrate 11 to form light conversion layers 14 of different colors (e.g. R, G, B). Specifically, the second substrate is attached to a side of the first substrate 11 on which the LEDs 12 are disposed.

In the LED array structures according to the embodiments of the present application, the LED chip is coated by filling the elastic portion 13 between the LEDs and between the LEDs and the first substrate. Therefore, the elastic portion 13 is used as the stress release layer during the bending process of the flexible screen, so as to prevent damage to the brittle LED chip and improve bending resistance of the LED array structure.

A display device according to a second embodiment of the present application includes the LED array structure mentioned in the first embodiment. Specific structure of the LED array structure is not described herein.

In the display device according to the embodiments of the present application, an LED chip is coated by filling elastic portion 13 between LEDs and between the LEDs and a first substrate. Therefore, the elastic portion 13 is used as a stress release layer during bending process of a flexible screen, so as to prevent damage to the brittle LED chip and improve bending resistance of the LED array structure.

The present application is not limited by the embodiments. Obviously, many modifications and variations can be made according to above descriptions. In order to explain principles and practical applications of the present application, the embodiments are selected and described in detail in a specification. Therefore, the present application may be well used or be modified to use by those skilled in the art. The present application is to be limited only by claims and full scopes and equivalents thereof.

What is claimed is:

1. An LED array structure, comprising:
a first substrate;
a plurality of LEDs formed on the first substrate; and
an elastic portion filled between the plurality of LEDs and the first substrate, and/or between the adjacent LEDs.

2. The LED array structure according to claim 1, wherein the elastic portion is made of at least one of polyurethane, silicone rubber and polyimide.

3. The LED array structure according to claim 1, wherein each of the plurality of LEDs comprises an electron layer, a light emitting layer, a hole layer and an electrode, and the light emitting layer is formed between the electron layer and the hole layer.

4. The LED array structure according to claim 3, wherein the electron layer, the light emitting layer and the hole layer are coated by the elastic portion.

5. The LED array structure according to claim 3, wherein the electron layer is a n-type GaN layer, and the hole layer is a p-type GaN layer; or
the electron layer is the p-type GaN layer, and the hole layer is the n-type GaN layer.

6. The LED array structure according to claim 3, further comprising a buffer layer formed on the hole layer or the electron layer.

7. The LED array structure according to claim 6, wherein the buffer layer is disposed away from the light emitting layer.

8. The LED array structure according to claim 7, wherein a material of the buffer layer comprises one or both of aluminum nitride and gallium nitride.

9. The LED array structure according to claim 6, wherein a material of the buffer layer comprises one or both of aluminum nitride and gallium nitride.

10. The LED array structure according to claim 1, wherein a material of the first substrate comprises at least one of polyethylene glycol terephthalate, polymethyl methacrylate, polyimide, polyurethane and silicone rubber.

11. The LED array structure according to claim 1, further comprising a second substrate attached to the first substrate, wherein the second substrate comprises a plurality of light conversion layers.

12. The LED array structure according to claim 11, wherein the second substrate is attached to a side of the first substrate on which the plurality of LEDs are disposed.

13. A display device comprising the LED array structure according to claim 1.
